(19) United States
(12) Patent Application Publication
(10) Pub. No.: US 2025/0056958 A1
(43) Pub. Date: Feb. 13, 2025

(54) QUANTUM DOT COMPLEX, MANUFACTURING METHOD THEREOF AND DISPLAY DEVICE COMPRISING THE SAME

(71) Applicant: Samsung Display Co., LTD., Yongin-si (KR)

(72) Inventors: Yun Ku JUNG, Yongin-si (KR); Yunhyuk KO, Yongin-si (KR); Won-Jun PARK, Yongin-si (KR); Chul Soon PARK, Yongin-si (KR); Seonhui BAEK, Yongin-si (KR); Sooho LEE, Yongin-si (KR); Jungho JO, Yongin-si (KR); Chang Yeol HAN, Yongin-si (KR)

(21) Appl. No.: 18/632,190

(22) Filed: Apr. 10, 2024

(30) Foreign Application Priority Data
Aug. 8, 2023 (KR) 10-2023-0103602

(51) Int. Cl. H10K 50/115; B82Y 40/00; C09K 11/02; C09K 11/88

(52) U.S. Cl. CPC H10K 50/115; B82Y 40/00; C09K 11/02; C09K 11/883

(57) ABSTRACT

A quantum dot complex according to an embodiment comprises a quantum dot; and a ligand bound to a surface of the quantum dot, wherein the surface of the quantum dot is provided with a plurality of coupling parts to which the ligand is bound; wherein the plurality of coupling parts include a first coupling part and a second coupling part. The ligand includes a first ligand bound to the first coupling part and a second ligand bound to the second coupling part, wherein the second ligand includes a halogen element. The halogen element is contained in an amount of 1 at % to 12 at % to the total content of the quantum dot complex.

This application claims priority to Korean Patent Application No. 10-2023-0103602, filed on Aug. 8, 2023, and all the benefits accruing therefrom under 35 U.S.C. § 119, the content of which in its entirety is herein incorporated by reference.

### BACKGROUND

### Field

The present disclosure relates to a quantum dot complex, a method for manufacturing the quantum dot complex, and a display device including the quantum dot complex.

### Description of the Related Art

Various display devices used in multimedia devices such as, for example, televisions, mobile phones, tablet computers, navigation devices, and game machines are being developed.

In some cases, such display devices may use a self-luminous type display element that may realize a display by emitting light from a light emitting material containing an organic compound.

Techniques for improving the color reproducibility of a display device are desired.

### SUMMARY

Embodiments of the present disclosure support a quantum dot complex with improved luminous efficiency. Embodiments of the present disclosure provide a method for producing a quantum dot complex with a simplified manufacturing process.

Embodiments of the present disclosure provide a display device with improved luminous efficiency.

A quantum dot complex according to an embodiment comprises a quantum dot; and a ligand bound to the surface of the quantum dot, wherein the surface of the quantum dots are provided with a plurality of coupling parts to which the ligand is bound, wherein the plurality of coupling parts includes a first coupling part and a second coupling part. The ligand includes: a first ligand bound to the first coupling part, and a second ligand coupled to the second coupling part. The second ligand includes a halogen element, and the halogen element is contained in an amount of 1 at % to 12 at % relative to a total content of the quantum dot complex.

The halogen element is one of: chlorine, wherein the chlorine is included in an amount of 5 at % to 7 at % relative to the total content of the quantum dot complex, bromine, wherein the bromine is included in an amount of 2 at % to 4 at % relative to the total content of the quantum dot complex, iodine, wherein the iodine is included in an amount of 1 at % to 2 at % relative to the total content of the quantum dot complex, and fluorine, wherein the fluorine is included in an amount of 9 at % to 12 at % relative to the total content of the quantum dot complex.

The quantum dot complex may have an organic content of 10 at % or more relative to the total content of the quantum dot complex.

The quantum dot complex may emit red light, and a valence band value of the quantum dot complex may be −5.60 eV to −5.80 eV.

The quantum dot complex may emit green light, and a valence band value of the quantum dot complex may be −5.73 eV to −5.93 eV.

The quantum dot complex may emit blue light, and a valence band value of the quantum dot complex may be −5.78 eV to −5.98 eV.

The plurality of coupling parts may further include a third coupling part, and the ligand may further include a third ligand coupled to a second coupling part or a third coupling part.

The third ligand may include any one selected from phosphine and phosphine oxide.

The third ligand may be a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 carbon atoms and a substituted or unsubstituted heteroaryl group having 2 to 30 carbon atoms.

The quantum dot may include a core and a shell surrounding the core.

The plurality of coupling parts may be provided on a surface of the shell.

The core may include a first semiconductor nanocrystal, the shell may include a second semiconductor nanocrystal different from the first semiconductor nanocrystal, and each of the first semiconductor nanocrystal and the second semiconductor nanocrystal may be selected from group II-VI compounds, group III-V compounds, group IV-VI compounds, group IV elements, group IV compounds, and combinations thereof.

A display device according to an embodiment includes a first electrode, a light emitting layer positioned on the first electrode, and a second electrode positioned on the light emitting layer, wherein the light emitting layer includes a quantum dot complex. The quantum dot complex includes a quantum dot; and a ligand bound to a surface of the quantum dot, wherein the surface of the quantum dot is provided with a plurality of coupling parts to which the ligand is bound, and wherein the plurality of coupling parts includes a first coupling part and a second coupling part. The ligand includes: a first ligand bound to the first coupling part, and a second ligand coupled to the second coupling part. The second ligand includes a halogen element, and the halogen element is included in an amount of 1 at % to 12 at % relative to a total content of the quantum dot complex.

The halogen element may be one of chlorine, fluorine, iodine, and bromine. The chlorine may be included in an amount of 5 at % to 7 at % based on the total content of the quantum dot complex, and the bromine may be included in an amount of 2 at % to 4 at % based on the total content of the quantum dot complex %, the iodine may be included in 1 at % to 2 at % based on the total content of the quantum dot complex, and the fluorine may be included in 9 at % to 12 at % based on the total content of the quantum dot complex.

The quantum dot complex may have an organic content of 10 at % or more relative to the total content of the quantum dot complex.

When the quantum dot complex emits red light, the quantum dot complex may have a valence band value of −5.60 eV to −5.80 eV, and when the quantum dot complex emits green light, the quantum dot complex may have a valence band value of −5.73 eV to −5.93 eV, and when the quantum dot complex emits blue light, a valence band value of the quantum dot complex may be −5.78 eV to −5.98 eV.

A method of manufacturing a quantum dot complex according to an embodiment includes providing a quantum dot and a first ligand bound to a surface of the quantum dot, and mixing and purifying the quantum dot complex in a first solution, wherein the first solution contains MX, wherein in the MX, M is any one of Na, Mg, K, Ca, Zn, In, Ga, Sn and Sb, and X is any one of F, Cl, Br, and I, and in the mixing and purifying the quantum dot complex with the first solution, a second ligand is bound to the surface of the quantum dots, and the second ligand includes the X.

The first solution may include a polar solvent, and the polar solvent may be methanol, ethanol, phenol, benzenediol, ethylene glycol, glycerol, diethylene glycol, triethylene glycol, ethylene glycol monoethyl ether, ethylene glycol monobutyl ether, or a combination thereof.

The MX may be provided at a concentration of 0.1 M to 0.5 M.

The method may further include performing surface treatment associated with binding a third ligand to the surface of the quantum dot prior to mixing and purifying the quantum dot complex in the first solution.

According to embodiments, a quantum dot complex having improved light emitting efficiency may be provided.

In some aspects, manufacturing cost and time associated with manufacturing may be reduced through a manufacturing method of a quantum dot complex having a simplified manufacturing process.

In some aspects, a display device having improved luminous efficiency may be provided.

### BRIEF DESCRIPTION OF THE DRAWINGS

FIG. 1 is a schematic diagram of a quantum dot complex according to an embodiment.

FIG. 2 is a cross-sectional view of a quantum dot complex according to an embodiment.

FIG. 3, FIG. 4, and FIG. 5 are each enlarged cross-sectional views of a portion of a quantum dot complex according to an embodiment.

FIG. 6 is a cross-sectional view of a quantum dot complex according to another embodiment.

FIG. 7 is an enlarged cross-sectional view of a portion of a quantum dot complex according to another embodiment.

FIG. 8 is a schematic cross-sectional view of a light emitting device according to an embodiment.

FIG. 9 is a schematic cross-sectional view of a display device according to an embodiment.

FIG. 10 is a flow chart according to a manufacturing process of a quantum dot complex according to an embodiment.

FIG. 11 is a schematic diagram of a quantum dot complex according to the manufacturing process of FIG. 10.

FIG. 12 is a flow chart according to a manufacturing process of a quantum dot complex according to an embodiment.

FIG. 13 is a schematic diagram of a quantum dot complex according to the manufacturing process of FIG. 12.

### DETAILED DESCRIPTION

Hereinafter, with reference to the accompanying drawings, various embodiments of supported by aspects of the present disclosure will be described in detail so that those skilled in the art can easily carry out the example embodiments supported by the present disclosure.

The example embodiments described herein may be of different forms and are not limited to the embodiments set forth herein.

In order to clearly describe the example embodiments supported by the present disclosure, some parts are omitted to prevent distracting from the description, and the same reference numerals are assigned to the same or similar components throughout the specification.

The size and thickness of each component shown in the drawings are arbitrarily shown for convenience of explanation, and the example embodiments described herein are not necessarily limited to the sizes and thicknesses described herein.

In the drawings, the thickness is shown enlarged to clearly express the various layers and regions.

In the drawings, for convenience of explanation, the thicknesses of some layers and regions are exaggerated.

When a part such as, for example, a layer, film, region, or plate is said to be “above” or “on” another part, this includes the case where the part is “directly on” the other part, and also the case where a further part exists between the part and the other part.

In contrast, when a part is referred to as being “directly on” another part, there are no intervening parts present between the part and the other part. Conversely, references to a part said to be “directly on” another part mean that there is no other part in between the part and the other part.

References to a part being “above” or “on” a reference part may mean being located above or below the reference part and is not necessarily limited to being located “above” or “on” the reference part in the opposite direction of gravity.

Throughout the specification, references of a certain component said to “include” a component means that the certain component may further include other components without excluding other components unless otherwise stated.

Throughout the specification, references made to a “planar image” mean when the target part is viewed from above, and references made to a “cross-sectional image” mean when the cross-section of the target part cut vertically is viewed from the side.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within +30%, 20%, 10%, 5% of the stated value, for example.

Aspects of the present disclosure support development of a display device using quantum dots as a light emitting material, which may improve the color reproducibility of a display device. Embodiments of the present disclosure support improvement of the luminous efficiency and lifespan of a display device using quantum dots.

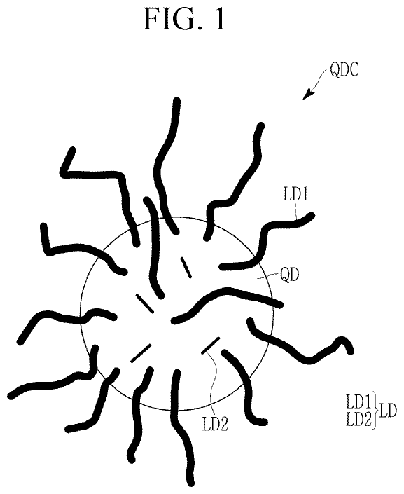

Hereinafter, a quantum dot complex according to an embodiment will be described with reference to FIGS. 1 to 5.

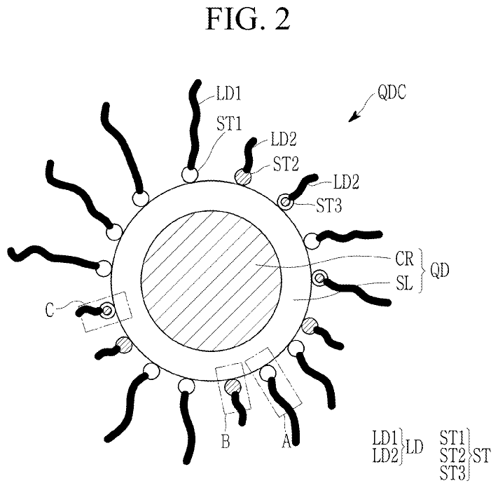

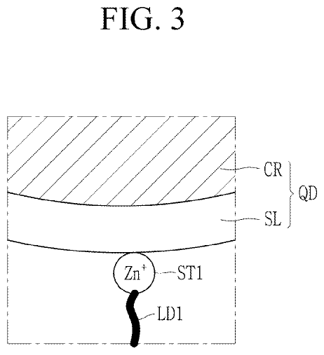

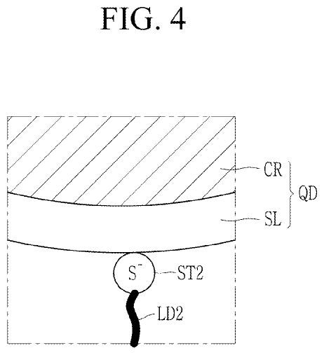

FIG. 1 is a schematic view of a quantum dot complex according to an embodiment, FIG. 2 is a cross-sectional view of the quantum dot complex according to an embodiment, and FIGS. 3, 4, and 5 are enlarged cross-sectional views of a portion of the quantum dot complex according to an embodiment.

Referring to FIGS. 1 and 2, a quantum dot complex QDC according to an embodiment may include a quantum dot QD and a ligand LD bound to a surface of the quantum dot QD.

The quantum dot complex QDC may include a ligand LD including a functional group. In some embodiments, the ligand LD attached to the surface of the quantum dot QD, and may have a modified surface property.

A quantum dot complex QDC may be referred to as a surface modified quantum dot.

The quantum dot QD may include a core CR and a shell SL surrounding the core CR.

However, embodiments supported by the present disclosure are not limited thereto, and the quantum dot QD may have a single-layer structure or a plurality of shells.

In the examples described herein, the quantum dots may be group II-VI compounds, group III-V compounds, group IV-VI compounds, group IV elements or compounds, group I-III-VI compounds, group II-III-VI compounds, group I-II-IV-VI compounds, or combinations thereof.

The group II-VI compound may be a binary element compound selected from the group consisting of CdSe, CdTe, ZnS, ZnSe, ZnTe, ZnO, HgS, HgSe, HgTe, MgSe, MgS, and mixtures thereof, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof. The group II-VI compound may be a ternary compound selected from the group consisting of quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group II-VI compound may further include a group III metal.

The group III-V compound may be a binary element compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AIPAs, AlPSb, InGaP, InNP, InNAs, InNSb, InPAs, InZnP, InPSb, and mixtures thereof; or a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof.

The group III-V compound may further include a group II metal (e.g., InZnP).

The group IV-VI compound may be a binary element compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof, and the group IV-VI compound may be selected from the group consisting of quaternary compounds selected from the group consisting of SnPbSSe, SnPbSeTe, SnPbSTe, and mixtures thereof.

The group IV element or compound may be a monoatomic compound selected from the group consisting of Si, Ge, and combinations thereof, and the group IV element or compound may be selected from the group consisting of a binary element compound selected from the group consisting of SiC, SiGe, and combinations thereof, but is not limited thereto.

Examples of the group I-III-VI compound include AgInGaS, CulnSe2, CuInS2, CuInGaSe, and CuInGaS, but the group I-III-VI compound is not limited thereto.

Examples of the group I-II-IV-VI compound include, but are not limited to, CuZnSnSe and CuZnSnS.

The group IV element or compound is an element selected from the group consisting of Si, Ge, and mixtures thereof; the group IV element or compound may be selected from the group consisting of a binary element compound selected from the group consisting of SiC, SiGe, and mixtures thereof.

The group II-III-VI compound may be selected from the group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and combinations thereof, but is not limited thereto.

The group I-II-IV-VI compound may be selected from CuZnSnSe and CuZnSnS, but is not limited thereto.

In quantum dots, the aforementioned two-element compound, three-element compound, and/or quaternary element compound may exist in a particle at a uniform concentration, or may be present in the same particle with a partially different concentration distribution.

In some embodiments, one quantum dot may have a core/shell structure surrounding another quantum dot.

The interface between the core and the shell may have a concentration gradient in which the concentration of elements present in the shell decreases toward the center.

In some embodiments, the quantum dots may have a core-shell structure including a core including the aforementioned nanocrystal and a shell surrounding the core.

The shell of the quantum dots may serve as a protective layer for maintaining semiconductor properties by preventing chemical deterioration of the core and/or as a charging layer for imparting electrophoretic properties to the quantum dots.

The shell may be monolayer or multilayer.

The interface between the core and the shell may have a concentration gradient in which the concentration of elements present in the shell decreases toward the center.

Examples of the quantum dot shell include metal or non-metal oxides, semiconductor compounds, or combinations thereof.

For example, the metal or nonmetal oxide may be SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or the metal or nonmetal oxide may be a binary element compound such as, for example, MgAl₂O₄, CoFe₂O₄, or NiFe₂O₄, CoMn₂O₄ and the like, but the embodiments supported by the present disclosure are not limited thereto.

In some aspects, examples of the semiconductor compound include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like. However, embodiments supported by the present disclosure are not limited thereto.

The interface between the core and the shell may have a concentration gradient in which the concentration of elements present in the shell decreases toward the center.

In some aspects, the semiconductor nanocrystal may have a structure including one semiconductor nanocrystal core and a multi-layered shell surrounding the semiconductor nanocrystal core.

In an embodiment, the multilayer shell may have two or more layers, such as, for example, two, three, four, five, or more layers.

Two adjacent layers of the shell may have a single composition or different compositions.

Each layer in the multilayer shell may have a composition that varies along a radius.

Quantum dots in accordance with example aspects of the present disclosure may have a full width of half maximum FWHM of the emission wavelength spectrum of about 45 nm or less, preferably about 40 nm or less, more preferably about 30 nm or less, and color purity or color reproducibility in the example ranges may be improved.

In some aspects, since light emitted through the quantum dots is emitted in all directions, a wide viewing angle may be improved.

In the quantum dots, the shell material and the core material may have different energy band gaps.

For example, the energy bandgap of the shell material may be larger than the energy bandgap of the core material.

In other embodiments, the energy bandgap of the shell material may be smaller than the energy bandgap of the core material.

The quantum dots may have multi-layered shells.

In a multi-layered shell, the energy bandgap of outer layers may be larger than the energy bandgap of inner layers (i.e., layers closer to the core).

In a multi-layered shell, the energy band gap of the outer layer may be smaller than the energy bandgap of the inner layer.

Quantum dots may control the absorption/emission wavelength by adjusting the composition and size.

The maximum emission peak wavelength of the quantum dots may have a wavelength range of ultraviolet to infrared wavelengths or higher.

Quantum dots may have a quantum efficiency of about 10% or more, such as, for example, about 30% or more, about 50% or more, about 60% or more, about 70% or more, about 90% or more, or even 100%.

Quantum dots may have a relatively narrow spectrum.

The quantum dots may have, for example, a full width at half maximum of an emission wavelength spectrum of about 50 nm or less—for example, about 45 nm or less, about 40 nm or less, or about 30 nm or less.

The quantum dots may have a particle size of about 1 nm or more and about 100 nm or less.

The size of the particle refers to the diameter of the particle or the diameter converted by assuming a spherical shape from a two-dimensional image obtained by transmission electron microscope analysis.

The quantum dots may have a thickness of about 1 nm to about 20 nm—for example, 2 nm or more, 3 nm or more, or 4 nm or more and 50 nm or less, 40 nm or less, 30 nm or less, 20 nm or less, 15 nm or less, such as, for example, 10 nm or less.

The shape of the quantum dots is not particularly limited to the examples described herein.

For example, the shape of the quantum dots may include, but is not limited to, a sphere, a polyhedron, a pyramid, a multipod, a square, a cuboid, a nanotube, a nanorod, a nanowire, a nanosheet, or a combination thereof.

Quantum dots are commercially available or may be suitably synthesized.

The particle size of quantum dots may be controlled relatively freely, and the particle size may be uniformly controlled during colloidal synthesis.

A quantum dot complex QDC according to an embodiment may include a ligand LD bound to a surface of the quantum dot QD.

A ligand LD according to an embodiment may include a first ligand LD1 and a second ligand LD2.

Each of the first ligand LD1 and the second ligand LD2 may be coupled to different coupling parts ST provided on the surface of the quantum dot QD.

In an embodiment, the shell SL of the quantum dot QD may include a plurality of coupling parts ST.

The plurality of coupling parts ST includes a first coupling part ST1, a second coupling part ST2, and a third coupling part ST3. In some embodiments, the first ligand LD1 is bound to the first coupling part ST1, and the second ligand LD2 may bind to the second coupling part ST2 or the third coupling part ST3.

FIG. 3 to FIG. 5 schematically show a form in which a ligand LD is bound to a surface of a quantum dot QD in a quantum dot complex QDC.

FIG. 3 is an enlarged view of portion A of FIG. 2, FIG. 4 is an enlarged view of portion B of FIG. 2, and FIG. 5 is an enlarged view of portion C of FIG. 2.

Referring to FIGS. 3 to 5, the plurality of coupling parts ST provided on the surface of the shell SL of the quantum dot QD may be defective portions exposed on the surfaces of semiconductor nanocrystals included in the shell SL.

Unlike atoms existing in a complete crystalline state inside the shell SL, the plurality of coupling parts ST may have a dangling bond to coordination unsaturation on the surface of the shell SL.

In an embodiment, the shell SL includes a group II-VI compound, a group III-V compound, a group IV-VI compound, and the like, and the shell SL includes groups II, III, IV, and V. In an embodiment, each group VI element may be exposed in a coordinated unsaturated state, or bound to a corresponding element but exposed in a coordinated unsaturated state to provide a plurality of bonding sites ST.

The plurality of coupling parts ST included in the shell SL may include a first coupling part ST1 exposed to positive ions, a second coupling part ST2 exposed to negative ions, and defects such as, for example, a vacancy may include a third coupling part ST3.

Referring to FIG. 3, the first ligand LD1 binds to the first coupling part ST1, and the first coupling part ST1 may be a defective portion where cations are exposed.

In FIG. 3, it is illustrated that the shell SL includes ZnS and the first coupling part ST1 is a Zn cation.

However, embodiments of the present disclosure are not limited thereto, and the first coupling part ST1 may be at least one selected from among Zn cations, Cd cations, Hg cations, Mg cations, Ag cations, Cu cations, Ga cations, Al cations, In cations, Sn cations, and Pb cations.

For example, the first ligand LD1 may include an electron-donating functional group in order to bind to the first coupling part ST1, which is a cation exposure defect part.

The first ligand LD1 may be a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 or more and 30 or less ring carbon atoms, and a substituted or unsubstituted heteroaryl group having 2 or more and 30 or less ring carbon atoms.

The first ligand LD1 may include a substituted or unsubstituted ethyl group, a substituted or unsubstituted octyl group, a substituted or unsubstituted dodecyl group, or a substituted or unsubstituted phenyl group.

The first ligand LD1 according to an embodiment may be oleic acid.

The terms “substituted or unsubstituted” in the present specification mean a deuterium atom, a halogen atom, a cyano group, a nitro group, an amino group, a silyl group, an oxy group, a thio group, a sulfinyl group, a sulfonyl group, a carbonyl group, a boron group, a phosphine group, an oxide group, a phosphine sulfide group, an alkyl group, an alkenyl group, an alkoxy group, a hydrocarbon ring group, an aryl group, and a heterocyclic group.

In some aspects, each of the example substituents described herein may be substituted or unsubstituted.

For example, a biphenyl group may be interpreted as an aryl group or a substituted phenyl group.

Referring to FIG. 4, the second ligand LD2 binds to the second coupling part ST2, and the second coupling part ST2 may be a defective portion where negative ions are exposed.

FIG. 4 illustrates an example in which the shell SL includes ZnS and the second coupling part ST2 is an S anion.

However, embodiments of the present disclosure are not limited thereto, and the second coupling part ST2 may be at least one selected from a S anion, a Se anion, a Te anion, an N anion, a Panion, an As anion, and an Sb anion.

The second ligand LD2 may include, for example, a halogen element, and may include, for example, at least one of fluorine, chlorine, bromine, and iodine.

The energy band position of the quantum dot complex QDC may be adjusted according to the type of the halogen element.

The halogen element may control the dipole on the surface of the quantum dot complex, and accordingly, the energy band position of the quantum dot complex is adjusted.

In general, when a halogen element is introduced, the energy band position is shifted in a negative direction, and the degree of shift may be controlled by the electron affinity of the halogen atom and the amount introduced into the quantum dot complex.

Referring to FIG. 5, the second ligand LD2 may bind to the third coupling part ST3. According to one or more embodiments of the present disclosure, the second ligand LD2 may bind to the third coupling part ST3 and to the second coupling part ST2.

The third coupling part ST3 may be a defect such as, for example, a vacancy or a defect exposed in a state in which cations and anions are bound.

The third coupling part ST3 may be a defect such as, for example, a vacancy. Alternatively or additionally, the third coupling part ST3 may be a defect portion in which cations and anions included in the shell SL combine to form a crystal, but in which some of the bonds are cut due to coordination unsaturation.

The quantum dot complex QDC according to an embodiment may include a halogen element by the second ligand LD2.

The quantum dot complex QDC may include a halide of 1 at % to 12 at % based on the total content of the quantum dot complex QDC.

For example, relative to the total content of the quantum dot complex, the quantum dot complex QDC may include chlorine Cl in an amount of 5 at % to 7 at %, or may contain bromine Br in an amount of 2 to 4 at %, iodine I contained in 1 at % to 2 at %, or fluorine F contained in 9 at % to 12 at %.

The quantum dot complex QDC according to an embodiment may include an organic material by the first ligand LD1.

For example, the quantum dot complex QDC may include an organic material included in an amount of 10 at % or more based on the total content of the quantum dot complex.

Since the quantum dot complex QDC according to an embodiment includes a sufficient amount of the first ligand LD1, the quantum dot complex QDC may have appropriate solubility.

The quantum dot complex QDC according to an embodiment may control the color of light emitted according to the particle size of the quantum dots QD, and accordingly, the quantum dots QD may have various luminous colors such as, for example, blue, red, and green.

As the particle size of the quantum dots QD is smaller, the quantum dot complex QDC may support emitting light in a shorter wavelength region.

For example, in quantum dots QD having the same core, the particle size of quantum dots emitting green light may be smaller than the particle size of quantum dots emitting red light.

In some aspects, in quantum dots QD having the same core, the particle size of quantum dots emitting blue light may be smaller than the particle size of quantum dots emitting green light.

However, embodiments supported by the present disclosure are not limited thereto, and even in quantum dots QD having the same core, the size of the particles may be adjusted depending on the material for forming the shell, the shell thickness, and the like.

In some aspects, when the quantum dots QD have various luminous colors such as, for example, blue, red, and green, the quantum dots QD having different luminous colors may have different core materials.

In an embodiment, for a quantum dot complex QDC capable of emitting red light, a valence band of the quantum dot complex QDC may be about-5.60 eV to −5.80 eV.

In an embodiment, for a quantum dot complex QDC capable of emitting green light, a valence band of the quantum dot complex QDC may be about-5.73 eV to −5.93 eV.

In an embodiment, for a quantum dot complex QDC capable of emitting blue light, a valence band of the quantum dot complex QDC may be about-5.78 eV to −5.98 eV.

The quantum dot complex according to an embodiment includes a first ligand and a second ligand stably bound to the surface of the quantum dot, and the binding of the ligands to the surface of the quantum dots may support a quantum dot complex having improved light efficiency.

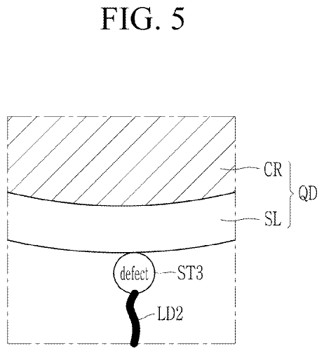

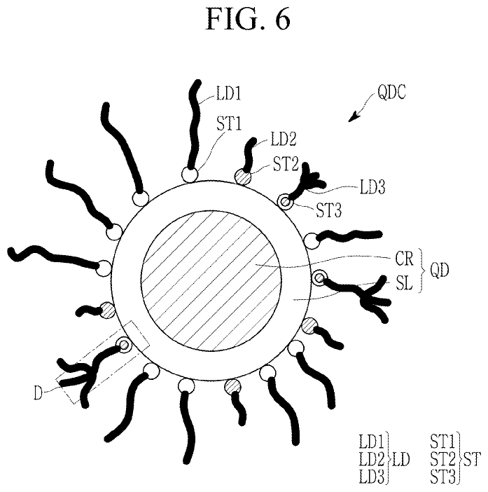

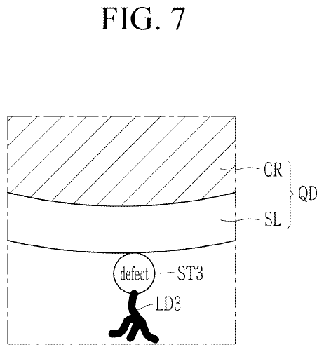

Hereinafter, a quantum dot complex according to another embodiment will be described with reference to FIGS. 6 and 7.

FIG. 6 is a cross-sectional view of a quantum dot complex according to another embodiment, and FIG. 7 is an enlarged cross-sectional view of a portion of the quantum dot complex according to another embodiment.

Descriptions of components identical to like components described herein will be omitted.

Referring to FIG. 6, a quantum dot complex QDC according to an embodiment may include a quantum dot QD and a ligand LD bound to a surface of the quantum dot QD.

The quantum dot complex QDC comprises a ligand LD including a functional group. In an embodiment, the ligand LD is attached to the surface of the quantum dot QD, and the surface of the quantum dot QD may have a modified surface property.

A quantum dot complex QDC may be referred to as a surface-modified quantum dot.

The quantum dot QD may include a core CR and a shell SL surrounding the core CR.

However, embodiments supported by the present disclosure are not limited thereto, and the quantum dot QD may have a single-layer structure or a plurality of shells.

A quantum dot complex QDC according to an embodiment may include a ligand LD bound to a surface of the quantum dot QD.

The ligand LD according to an embodiment may include a first ligand LD1, a second ligand LD2, and a third ligand LD3.

Each of the first ligand LD1, the second ligand LD2, and the third ligand LD3 may be coupled to different coupling parts ST provided on the surface of the quantum dot QD.

In an embodiment, the shell SL of the quantum dot QD may provide or include a plurality of coupling parts ST.

The plurality of coupling parts ST include a first coupling part ST1, a second coupling part ST2, and a third coupling part ST3, and the first ligand LD1 is attached to the first coupling part ST1. The second ligand LD2 may bind to the second coupling part ST2 or the third coupling part ST3, and the third ligand LD3 may bind to the second coupling part ST2 or the third coupling part ST3.

FIG. 7 is an enlarged view of part D of FIG. 6.

The third ligand LD3 according to an embodiment may be any one selected from phosphine, phosphine oxide, imidazole, and pyridine bound to the surface of the quantum dot QD.

In some aspects, the third ligand LD3 may be a substituted or unsubstituted alkyl group having 1 to 30 carbon atoms, a substituted or unsubstituted alkenyl group having 2 to 30 carbon atoms, a substituted or unsubstituted thiol group, or a substituted or unsubstituted oxy group, a substituted or unsubstituted aryl group having 6 or more and 30 or less ring carbon atoms, and a substituted or an unsubstituted heteroaryl group having 2 or more and 30 or less ring carbon atoms.

The quantum dot complex QDC according to an embodiment may include a halogen element by the second ligand LD2.

For example, the quantum dot complex QDC may include chlorine Cl in an amount of 5 at % to 7 at %, or contain bromine Br in an amount of 2 at % to 4 at %, iodine I contained in 1 at % to 2 at %, or fluorine F contained in 9 at % to 12 at % relative to the total content of the quantum dot complex QDC.

The quantum dot complex QDC according to an embodiment may include an organic material by the first ligand LD1 and the third ligand LD3.

For example, the quantum dot complex QDC may include an organic material included in an amount of 10 at % or more relative to the total content of the quantum dot complex.

In some aspects, since the quantum dot complex QDC according to an embodiment includes sufficient amounts of the first ligand LD1 and the third ligand LD3, the quantum dot complex QDC may have appropriate solubility.

The quantum dot complex QDC according to an embodiment may control the color of light emitted according to the particle size of the quantum dots QD, and accordingly, the quantum dots QD may have various luminous colors such as, for example, blue, red, and green.

As the particle size of the quantum dots QD is smaller, the quantum dot complex QDC may support emitting light in a shorter wavelength region.

For example, in quantum dots QD having the same core, the particle size of quantum dots emitting green light may be smaller than the particle size of quantum dots emitting red light.

In some aspects, in quantum dots QD having the same core, the particle size of quantum dots emitting blue light may be smaller than the particle size of quantum dots emitting green light.

However, embodiments supported by the present disclosure are not limited thereto, and even in quantum dots QD having the same core, the particle size may be adjusted according to the material for forming the shell, the shell thickness, and the like.

In some aspects, when the quantum dots QD have various luminous colors such as, for example, blue, red, and green, the quantum dots QD having different luminous colors may have different core materials.

In an embodiment, for a quantum dot complex QDC capable of emitting red light, a valence band of the quantum dot complex QDC may be about-5.60 eV to −5.80 eV.

In an embodiment, for a quantum dot complex QDC capable of emitting green light, a valence band of the quantum dot complex QDC may be about-5.73 eV to −5.93 eV.

In an embodiment, for a quantum dot complex QDC capable of emitting blue light, a valence band of the quantum dot complex QDC may be about-5.78 eV to −5.98 eV.

The quantum dot complex according to an embodiment includes a first ligand, a second ligand, and a third ligand stably bound to the surface of the quantum dots, and the binding of the ligands to the surface of the quantum dots may support a quantum dot complex having improved light efficiency may be provided.

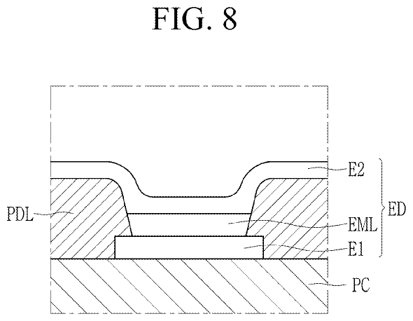

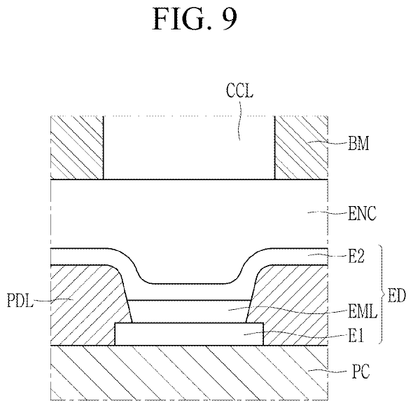

Hereinafter, a display device according to an embodiment will be described with reference to FIGS. 8 and 9.

FIG. 8 is a schematic cross-sectional view of a light emitting device according to an embodiment, and FIG. 9 is a schematic cross-sectional view of a display device according to an embodiment.

Referring first to FIG. 8, a display device according to an embodiment may include a light emitting element ED.

The light emitting element ED includes a first electrode E1, a light emitting layer EML, and a second electrode E2.

The first electrode E1 is also referred to as an anode electrode, and may be composed of a single layer including a transparent conductive oxide layer or a metal material, or a multi-layer including a transparent conductive oxide layer or a metal material.

The transparent conductive oxide layer may include indium tin oxide ITO, poly-ITO, indium zinc oxide IZO, indium gallium zinc oxide IGZO, and indium tin zinc oxide ITZO.

The metal material may include silver Ag, molybdenum Mo, copper Cu, gold Au, and aluminum Al.

The first electrode E1 may be electrically connected to the pixel circuit unit PC positioned below the first electrode E1.

The pixel circuit unit PC may include a transistor, and the first electrode E1 may receive an output current to be transmitted from the pixel circuit unit PC to the light emitting layer EML.

A pixel defining layer PDL may be positioned on the first electrode E1.

The pixel defining layer PDL includes an opening overlapping at least a portion of the first electrode E1.

The pixel defining layer PDL may define a formation position of the light emitting layer EML such that the light emitting layer EML may be positioned on the exposed portion of the upper surface of the first electrode E1.

The light emitting layer EML may be positioned within the pixel opening defined by the pixel defining layer PDL.

The light emitting layer EML according to an embodiment may include the quantum dot complex described herein.

Although the light emitting layer EML is shown as a single layer in FIG. 8, auxiliary layers such as, for example, an electron injection layer, an electron transport layer, a hole transport layer, and a hole injection layer may also be included above and/or below the light emitting layer EML. A hole injection layer and a hole transport layer may be positioned below the light emitting layer EML, and an electron transport layer and an electron injection layer may be positioned above the light emitting layer EML.

The second electrode E2 may be positioned on the pixel defining layer PDL and the light emitting layer EML.

The second electrode E2 is also referred to as a cathode electrode and is formed of a transparent conductive layer including indium tin oxide ITO, indium zinc oxide IZO, indium gallium zinc oxide IGZO, and indium tin zinc oxide ITZO.

In some aspects, the second electrode E2 may have a translucent property, and in this case, a micro-cavity may be formed together with the first electrode E1.

According to the micro-cavity structure, light of a specific wavelength is emitted upward due to the spacing and characteristics between both electrodes, and as a result, red, green, or blue colors may be displayed.

Referring to FIG. 9, a display device according to an embodiment includes a pixel circuit unit PC, a light emitting element ED connected to the pixel circuit unit PC, and a color conversion unit CCL positioned on the light emitting element ED.

Repeated descriptions of like elements described herein are omitted for brevity.

The light emitting layer EML according to an embodiment may include an organic material emitting red, green, and blue light.

The light emitting layer EML emitting red, green, and blue light may include a low-molecular or high-molecular organic material.

Although the example of FIG. 9 shows the light emitting layer EML as a single layer, auxiliary layers such as, for example, an electron injection layer, an electron transport layer, a hole transport layer, and a hole injection layer may be included above and/or below the light emitting layer EML, a hole injection layer and a hole transport layer may be positioned below the EML, and an electron transport layer and an electron injection layer may be positioned above the light emitting layer EML.

The encapsulation layer ENC may be positioned on the second electrode E2.

The encapsulation layer ENC may include at least one inorganic layer and at least one organic layer.

The display device according to an embodiment may include a color conversion layer CCL overlapping the light emitting element ED.

The color conversion layer CCL may include the above-described quantum dot complex.

For example, the color conversion layer CCL positioned in the red light emitting region may include a red quantum dot complex, and the color conversion layer CCL positioned in the green light emitting region may include a green quantum dot complex.

A partition wall BM may be positioned between adjacent color conversion layers CCL, contain a black material capable of blocking light, and may prevent color mixing between adjacent light emitting regions.

A display device including the quantum dot complex described above may provide improved luminous efficiency.

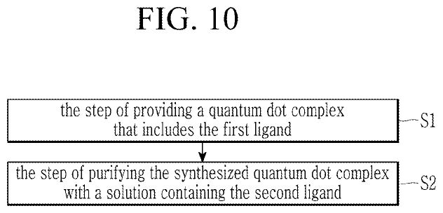

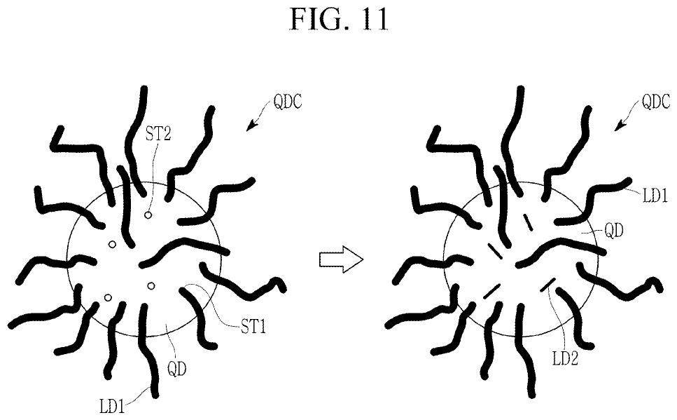

Hereinafter, a method for manufacturing a quantum dot complex according to an embodiment will be described with reference to FIGS. 10 and 11.

FIG. 10 is a flowchart illustrating a manufacturing process of a quantum dot complex according to an embodiment, and FIG. 11 is a schematic diagram of a quantum dot complex according to the manufacturing process of FIG. 10.

Referring to FIG. 10, the quantum dot complex according to an embodiment is formed by the step of forming a quantum dot complex to which a first ligand LD1 is bound (at S1), and mixing and purification the quantum dot complex with a first solution including a second ligand (at S2).

Referring to FIGS. 10 and 11, the quantum dot complex QDC may be provided in the form of a quantum dot QD including a first ligand LD1 on the surface of the quantum dot complex QD.

In some aspects, most of the first ligand LD1 may be provided in a form combined with the first coupling part ST1 (e.g., at S1).

In some aspects, the manufacturing process includes mixing the quantum dot complex QDC including the first ligand LD1 with a first solution containing MX to be purified (e.g., at S2).

By mixing the quantum dot complex QDC with the first solution as described with reference to FIGS. 10 and 11, the quantum dot complex QDC may include the second ligand LD2 coupled to the second coupling part ST2 and a purification process may be performed at the same time.

In some aspects, the purification process may remove unnecessary by-products and extra ligands.

In an example, in the MX, M may be any one of Na, Mg, K, Ca, Zn, In, Ga, Sn, and Sb, and X may be any one of F, Cl, Br, and I.

The MX may be provided at a concentration of 0.1 M to 0.5 M in a polar solvent.

The polar solvent may include, for example, methanol, ethanol, phenol, benzenediol, ethylene glycol, glycerol, diethylene glycol, triethylene glycol, ethylene glycol monoethyl ether, ethylene glycol monobutyl ether, or any combination thereof, but is not limited thereto.

Through the manufacturing process described with reference to FIGS. 10 and 11, the quantum dot complex QDC described in FIGS. 1 to 5 may be obtained.

The quantum dot complex QDC prepared through the manufacturing method described with reference to FIGS. 10 and 11 may include a halogen element by the second ligand LD2.

For example, the quantum dot complex QDC may include chlorine Cl in an amount of 5 at % to 7 at %, bromine Br in an amount of 2 to 4 at %, Iodine I in an amount of 1 at % to 2 at %, or fluorine F in an amount of 9 at % to 12 at % based on the total content of the quantum dot complex QDC.

The quantum dot complex QDC prepared through the manufacturing method described with reference to FIGS. 10 and 11 may include an organic material by the first ligand LD1.

For example, the quantum dot complex QDC may include an organic material included in an amount of 10 at % or more relative to the total content of the quantum dot complex.

Since the quantum dot complex QDC according to an embodiment includes a sufficient amount of the first ligand LD1, the quantum dot complex QDC may have appropriate solubility.

In an embodiment, for a quantum dot complex QDC manufactured through the manufacturing methods described herein with reference to FIGS. 10 and 11 and capable of emitting red light, the quantum dot complex QDC may have a valence band of about-5.70 eV.

In an embodiment, for a quantum dot complex QDC manufactured through the manufacturing methods described herein with reference to FIGS. 10 and 11 and capable of emitting green light, a valence band of the quantum dot complex QDC may be about-5.83 eV.

In an embodiment, for a quantum dot complex QDC manufactured through the manufacturing methods described herein with reference to FIGS. 10 and 11 and capable of emitting blue light, a valence band of the quantum dot complex QDC may be about-5.88 eV.

In some alternative embodiments, when a surface treatment process is performed to include the second ligand LD2, the valence band of a quantum dot complex QDC emitting red light may be about-5.20 eV to −5.33 eV, the valence band of a quantum dot complex QDC emitting green light may be about-5.35 eV to −5.48 eV, and the valence band of a quantum dot complex QDC emitting blue light may be about-6.25 eV to −6.36 eV.

According to the manufacturing method according to an embodiment, the valence band of the quantum dot complex QDC that emits red light may be negatively shifted by about 0.37 eV to 0.50 eV, the valence band of the quantum dot complex QDC that emits green light may be negatively shifted by about 0.35 eV to 0.48 eV, and the valence band of the quantum dot complex QDC that emits blue light may be negatively shifted by about 0.37 eV to 0.48 eV.

In another example, after forming the quantum dot complex including the first ligand, a surface treatment may be performed at a high temperature such that the quantum dot complex includes the second ligand LD2, and then a purification process may be performed.

According to this process, a problem in that the first ligand LD1 may be removed during the surface treatment of the second ligand LD2 may occur, and the efficiency of the quantum dot complex QDC may be decreased.

However, according to an embodiment, the quantum dot complex may be surface-treated to include the second ligand LD2 in a purification process performed at room temperature, which may prevent occurrences of the removal of the first ligand LD1.

Accordingly, for example, the manufacturing process described herein of binding the second ligand LD2 may be simplified, and the first ligand LD1 and the second ligand LD1 may be stably bound to the quantum dot complex QDC, thereby providing a quantum dot complex QDC with improved efficiency.

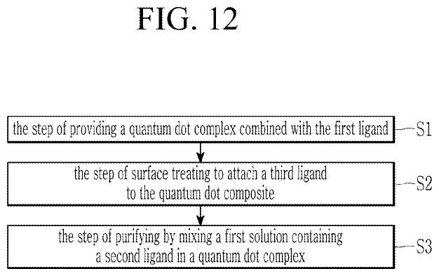

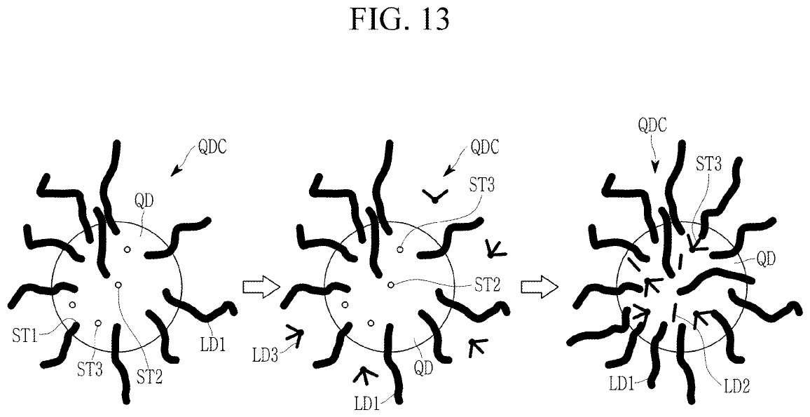

Hereinafter, a method for manufacturing a quantum dot complex according to another embodiment will be described with reference to FIGS. 12 and 13.

FIG. 12 is a flow chart according to a manufacturing process of a quantum dot complex according to an embodiment, and FIG. 13 is a schematic diagram of a quantum dot complex according to the manufacturing process of FIG. 12.

Referring to FIG. 12, the manufacturing process of the quantum dot complex according to an embodiment may be manufactured through a step S1 of providing a quantum dot complex combined with a first ligand LD1, a step S2 of surface treatment to combine a third ligand LD3 with the quantum dot complex, and a step S3 of purifying by mixing the quantum dot complex in a first solution containing a second ligand.

Compared to the example manufacturing process described with reference to FIG. 10, the manufacturing process described with reference to FIG. 12 may further include a surface treatment step S2 which binds the third ligand LD3 to the quantum dot complex QDC.

Referring to FIGS. 12 and 13, the quantum dot complex QDC may be provided in the form of quantum dot QD including a first ligand LD1 on the surface of the quantum dot QD.

In some aspects, most of the first ligand LD1 may be provided in a form combined with the first coupling part ST1 (e.g., at S1).

In some aspects, the manufacturing process includes mixing the quantum dot complex QDC with a solution containing the third ligand LD3 and an organic solvent, and the QDC is reacted at room temperature for about 30 minutes.

The organic solvent may include hexane, toluene, chloroform, dimethyl sulfoxide, or dimethyl formamide.

However, embodiments supported by the present disclosure are not limited thereto.

The third ligand LD3 may include any one selected from phosphine, phosphine oxide, imidazole, and pyridine bound to the surface of the quantum dot QD.

In some aspects, the third ligand LD3 may be a substituted or unsubstituted alkyl group having 1 to 30 carbon atoms, a substituted or unsubstituted alkenyl group having 2 to 30 carbon atoms, a substituted or unsubstituted thiol group, or a substituted or unsubstituted oxy group, a substituted or unsubstituted aryl group having 6 or more and 30 or less ring carbon atoms, and a substituted or unsubstituted heteroaryl group having 2 or more and 30 or less ring carbon atoms.

The quantum dot complex QDC subjected to such a surface treatment process may have a form including a first ligand LD1 and a third ligand LD3.

In an example, the quantum dot complex QDC including the first ligand LD1 and the third ligand LD3 may be provided to be dispersed in the first solution including MX.

By providing the quantum dot complex QDC including the first ligand LD1 and the third ligand LD3 to be dispersed in the first solution including MX, a purification process may be performed simultaneously with obtaining a quantum dot complex QDC including the second ligand LD2.

In some aspects, the purification process may remove unnecessary by-products and extra ligands.

In the MX, M may be any one of Na, Mg, K, Ca, Zn, In, Ga, Sn, and Sb, and X may be any one of F, Cl, Br, and I.

The MX may be provided at a concentration of 0.1 M to 0.5 M in the polar solvent.

The polar solvent may include, for example, methanol, ethanol, phenol, benzenediol, ethylene glycol, glycerol, diethylene glycol, triethylene glycol, ethylene glycol monoethyl ether, ethylene glycol monobutyl ether, or any combination thereof, but not limited thereto.

Through the manufacturing process described with reference to FIGS. 12 and 13, the quantum dot complex QDC described in FIGS. 6 to 7 may be obtained.

The quantum dot complex QDC prepared through the described manufacturing method may include a halogen element by the second ligand LD2.

For example, the quantum dot complex QDC may include chlorine Cl contained in an amount of 5 at % to 7 at %, bromine Br contained in an amount of 2 at % to 4 at %, iodine I contained in 1 at % to 2 at %, or fluorine F contained in 9 at % to 12 at % relative to the total content of the quantum dot complex.

The quantum dot complex QDC prepared through the manufacturing method described with reference to FIGS. 12 and 13 may include an organic material by the first ligand LD1 and the third ligand LD3.

For example, the quantum dot complex QDC may include an organic material contained in an amount of 10 at % or more relative to the total content of the quantum dot complex QDC.

Since the quantum dot complex QDC according to an embodiment includes sufficient amounts of the first ligand LD1 and the third ligand LD3, the quantum dot complex QDC may have appropriate solubility.

In an embodiment, for a quantum dot complex QDC manufactured through the manufacturing methods described herein with reference to FIGS. 12 and 13 and capable of emitting red light, the quantum dot complex QDC may have a valence band of about-5.70 eV.

In an embodiment, for a quantum dot complex QDC manufactured through the manufacturing methods described herein with reference to FIGS. 12 and 13 and capable of emitting green light, a valence band of the quantum dot complex QDC may be about-5.83 eV.

In an embodiment, for a quantum dot complex QDC manufactured through the manufacturing methods described herein with reference to FIGS. 12 and 13 and capable of emitting blue light, a valence band of the quantum dot complex QDC may be about-5.88 eV.

In some alternative embodiments, when a separate surface treatment process is performed to include the second ligand LD2, the valence band of a quantum dot complex QDC emitting red light may be about-5.20 eV to −5.33 eV, the valence band of a quantum dot complex QDC emitting green light may be about-5.35 eV to −5.48 eV, and the valence band of a quantum dot complex QDC emitting blue light may be about-6.25 eV to −6.36 eV.

According to the manufacturing method according to an embodiment, the valence band of the quantum dot complex QDC emitting red light may be negative-shifted by about 0.37 eV to 0.50 e V, the valence band of the quantum dot complex QDC emitting green light may be negative-shifted by about 0.35 eV to 0.48 eV, and the valence band of the quantum dot complex QDC emitting blue light may be negative-shifted by about 0.37 eV to 0.48 eV.

In another example, after forming the quantum dot complex including the first ligand, a surface treatment may be performed at a high temperature such that the quantum dot complex includes the second ligand LD2 and the third ligand LD3, and then a purification process may be performed.

According to this process, a problem in which the first ligand LD1 is removed may occur in the process of surface treating the second ligand LD2 and the third ligand LD3, and thus the efficiency of the quantum dot complex QDC may be decreased.

However, according to the embodiment, the quantum dot complex may be surface-treated to include the second ligand LD2 in a purification process performed at room temperature.

According to this, the manufacturing process of binding the second ligand may be simplified, and the first ligand LD1, the second ligand LD2, and the third ligand LD3 may be stably bound to the quantum dot complex QDC, thereby providing a quantum dot complex QDC with improved efficiency.

Hereinafter, comparative example 1, comparative example 2, embodiment 1, and embodiment 2 will be described with reference to Table 1.

Comparative example 1 is a quantum dot complex in which blue quantum dots in the form of ZnTeSe/ZnSe/ZnS are purified using ethanol, and comparative example 2 is a quantum dot complex in which blue quantum dots in the form of ZnTeSe/ZnSe/ZnS are surface treated with ZnCl2 and then purified using ethanol. Embodiment 1 is a quantum dot complex obtained by purifying blue quantum dots in the form of ZnTeSe/ZnSe/ZnS using ethanol containing ZnCl2, and embodiment 2 is a complex of blue quantum dots in the form of ZnTeSe/ZnSe/ZnS using ethanol containing ZnI2.

TABLE 1

| | comparative | comparative | embodi- | embodi- |
|---|---|---|---|---|
| item | example 1 | example 2 | ment 1 | ment 2 |
| PLQY | 38% | 45% | 71% | 82% |
| valence | −5.79 eV | −5.88 eV | −6.36 eV | −6.25 eV |
| band | | | | |
| organic | 14.87% | 9.04% | 10.88% | 11.85% |
| material content | | | | |

Referring to Table 1, in the case of embodiment 1 and embodiment 2, it was confirmed that the light efficiency was significantly improved to 71% and 82%, respectively, compared to comparative example 1 (38%) and comparative example 2 (45%).

In the case of embodiment 1 and embodiment 2, it was confirmed that the valence band value was negatively shifted compared to comparative example 1 and comparative example 2.

In some aspects, the negative shifting resulted due to an increase in the amount of the surface-treated second ligand.

According to the negatively shifted valence band value, the band-offset between the quantum dots and the electron transport layer may be reduced, and device efficiency may be improved by improving electron injection.

In some aspects, embodiment 1 and embodiment 2 may include 10 at % or more of the organic ligand, compared to comparative example 2.

Accordingly, for example, when the organic ligand is stably bound to the quantum dot surface, and the ink including the quantum dot complex is prepared, ejection stability may be improved through the control of precipitation of the organic material.

In contrast, in another example embodiment, when the purification process was performed with ethanol containing ZnCl₂ according to the manufacturing process according to an embodiment, it was confirmed that Cl included in the quantum dot complex was included at about 6.89 at %.

In some aspects, when the purification process was performed with ethanol containing ZnBr₂ according to the manufacturing process according to an embodiment, it was confirmed that Br included in the quantum dot complex was included at about 2.96 at %.

In some aspects, when the purification process was performed with ethanol containing ZnI₂ according to the manufacturing process according to an embodiment, it was confirmed that I included in the quantum dot complex was included at about 1.86 at %.

It was confirmed that the quantum dot complex prepared by the manufacturing process according to an embodiment may provide a plurality of ligands stably bound to the coupling part, thereby providing quantum dots with improved luminous efficiency.

Although the embodiments supported by aspects of the present disclosure have been described in detail herein, the scope of embodiments supported by the present disclosure are not limited thereto, and various modifications and improvements of those skilled in the art using the concepts defined in the following claims are also included in the scope of the present disclosure.

What is claimed is:

1. A quantum dot complex, comprising:
a quantum dot; and
a ligand bound to a surface of the quantum dot,
wherein the surface of the quantum dot is provided with a plurality of coupling parts to which the ligand is bound,
wherein the plurality of coupling parts comprises a first coupling part and a second coupling part,
wherein the ligand comprises:
a first ligand bound to the first coupling part, and
a second ligand coupled to the second coupling part, wherein:
the second ligand includes a halogen element, and
the halogen element is contained in an amount of 1 at % to 12 at % relative to a total content of the quantum dot complex.

2. The quantum dot complex of claim 1, wherein:
the halogen element is one of:
chlorine, wherein the chlorine is included in an amount of 5 at % to 7 at % relative to the total content of the quantum dot complex,
bromine, wherein the bromine is included in an amount of 2 at % to 4 at % relative to the total content of the quantum dot complex,
iodine, wherein the iodine is included in an amount of 1 at % to 2 at % relative to the total content of the quantum dot complex, and
fluorine, wherein the fluorine is included in an amount of 9 at % to 12 at % relative to the total content of the quantum dot complex.

3. The quantum dot complex of claim 1, wherein:
the quantum dot complex has an organic content of 10 at % or more relative to the total content of the quantum dot complex.

4. The quantum dot complex of claim 1, wherein:
the quantum dot complex emits red light, and
a valence band value of the quantum dot complex is-5.60 eV to −5.80 eV.

5. The quantum dot complex of claim 1, wherein:
the quantum dot complex emits green light, and
a valence band value of the quantum dot complex is-5.73 eV to −5.93 eV.

6. The quantum dot complex of claim 1, wherein:
the quantum dot complex emits blue light, and
a valence band value of the quantum dot complex is-5.78 eV to −5.98 eV.

7. The quantum dot complex of claim 1, wherein:
the plurality of coupling parts further comprise a third coupling part, and
the ligand further comprises a third ligand coupled to the second coupling part or the third coupling part.

8. The quantum dot complex of claim 7, wherein:
the third ligand is any one selected from phosphine and phosphine oxide.

9. The quantum dot complex of claim 8, wherein:
the third ligand further comprises a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 carbon atoms, and a substituted or unsubstituted heteroaryl group having 2 to 30 carbon atoms.

10. The quantum dot complex of claim 1, wherein:
the quantum dot comprises a core and a shell surrounding the core.

11. The quantum dot complex of claim 10, wherein:
the plurality of coupling parts are provided on a surface of the shells.

12. The quantum dot complex of claim 10, wherein:
the core includes a first semiconductor nanocrystal,
the shell includes a second semiconductor nanocrystal different from the first semiconductor nanocrystal, and
each of the first semiconductor nanocrystal and the second semiconductor nanocrystal is selected from group II-VI compounds, group III-V compounds, group IV-VI compounds, group IV elements, group IV compounds, and combinations thereof.

13. A display device, comprising:
a first electrode;
a light emitting layer positioned on the first electrode, and
a second electrode positioned on the light emitting layer, the light emitting layer including a quantum dot complex,
wherein the quantum dot complex comprises:
a quantum dot; and
a ligand bound to a surface of the quantum dot,
wherein the surface of the quantum dot is provided with a plurality of coupling parts to which the ligand is bound,
wherein the plurality of coupling parts comprises a first coupling part and a second coupling part,
wherein the ligand comprises:
a first ligand bound to the first coupling part, and
a second ligand coupled to the second coupling part;
wherein:
the second ligand includes a halogen element, and
the halogen element is included in an amount of 1 at % to 12 at % relative to a total content of the quantum dot complex.

14. The display device of claim 13, wherein:
the halogen element is one of:
chlorine, wherein the chlorine is included in an amount of 5 at % to 7 at % relative to the total content of the quantum dot complex,
bromine, wherein the bromine is included in an amount of 2 at % to 4 at % relative to the total content of the quantum dot complex,
iodine, wherein the iodine is included in an amount of 1 at % to 2 at % relative to the total content of the quantum dot complex, and
fluorine, wherein the fluorine is included in an amount of 9 at % to 12 at % relative to the total content of the quantum dot complex.

15. The display device of claim 13, wherein:
the quantum dot complex has an organic content of 10 at % or more relative to the total content of the quantum dot complex.

16. The display device of claim 13, wherein:
when the quantum dot complex emits red light, a valence band value of the quantum dot complex is-5.60 eV to −5.80 eV,
when the quantum dot complex emits green light, the valence band value of the quantum dot complex is-5.73 eV to −5.93 eV, and
when the quantum dot complex emits blue light, the valence band value of the quantum dot complex is-5.78 eV to −5.98 eV.

17. A method for producing a quantum dot complex, comprising:
providing a quantum dot and a first ligand bound to a surface of the quantum dot; and
mixing and purifying the quantum dot complex in a first solution, wherein the first solution contains MX,
wherein:
in the MX, M is any one of Na, Mg, K, Ca, Zn, In, Ga, Sn, and Sb, and X is any one of F, Cl, Br, and I, and
in the mixing and purifying the quantum dot complex in the first solution, a second ligand is bound to the surface of the quantum dot, and the second ligand includes the X.

18. The method of claim 17, wherein:
the first solution includes a polar solvent,
the polar solvent is methanol, ethanol, phenol, benzenediol, ethylene glycol, glycerol, diethylene glycol, triethylene glycol, ethylene glycol monoethyl ether, ethylene glycol monobutyl ether, or a combination thereof.

19. The method of claim 17, wherein:
the MX is provided at a concentration of 0.1 M to 0.5 M.

20. The method of claim 17, further comprising:
performing surface treatment associated with binding a third ligand to the surface of the quantum dot prior to mixing and purifying the quantum dot complex in the first solution.
